(19) United States
(12) Patent Application Publication
(10) Pub. No.: US 2005/0116259 A1
(43) Pub. Date: Jun. 2, 2005

(54) Solid-state imaging device and method of driving the same

(76) Inventor: Hirofumi Komori, Kanagawa (JP)

Correspondence Address: BIRCH STEWART KOLASCH & BIRCH, PO BOX 747, FALLS CHURCH, VA, 22040-0747, US

(21) Appl. No.: 10/775,222

(22) Filed: Feb. 11, 2004

(30) Foreign Application Priority Data
Nov. 27, 2003 (JP) 2003-397924

(51) Int. Cl. H01L 29/768

(52) U.S. Cl. 257/222

(57) ABSTRACT

The MOS type solid-state imaging device has plural pixels each of which comprises a photo-diode and a photo-detector on a substrate. The photo-diode has a charge generating region to generate photo-generated charges upon light illumination. The photo-detector has a well region with a hole pocket to accumulate the photo-generated charges transferred from the charge generating region via a transfer region provided therebetween. The potential in the source region of the photo-detector changes in accordance with the amount of the photo-generated charges in the hole pocket. The potential in the transfer region may be removed by controlling the voltage to the photo-detector. In the photo-diode, a p⁺-type impurity region as the lateral overflow drain region is provided for ejecting the photo-generated charges from the charge generating region.

### BACKGROUND OF THE INVENTION

1. Field of the Invention

The present invention relates to a threshold modulation type solid-state imaging device for use in video cameras, digital cameras, scanners, camera-equipped mobile phones, or the like, and to a method of driving such solid-state imaging device.

2. Description of Related Art

Solid-state imaging devices of charged coupled device (CCD) type and metal oxide silicon (MOS) type have been widely used in most image input devices because they can be mass produced using advanced fine patterning techniques. Especially, MOS type solid-state imaging devices have gained a great deal of attention because of the advantages that MOS type solid-state imaging devices have lower power consumption than CCD type, and that they can be easily incorporated in peripheral circuit therefor by use of common complementary MOS (CMOS) fabrication technique. On account of these advantages, MOS type solid-state imaging devices have been improved. For example, U.S. Pat. No. 6,051,857 (corresponding to Japan Patent No. 2935492) describes the MOS type solid-state imaging device in which a carrier pocket (hole pocket) is formed below the channel region of the MOS type transistor to accumulate photo-generated charges (holes) transferred from a charge generating region. The threshold voltage (corresponding to the source potential) of the MOS type transistor depends on the amount of accumulated charges in the carrier pocket. Thus, it is possible to obtain image signals by detecting the source potential.

The above MOS type solid-state imaging device is configured such that the photo-generated charges in the charge generating region are sequentially moved to the carrier pocket. Because the photo-generated charges are generated in the pixels of one horizontal line and moved to the carrier pocket while the image signals of the pixels on other horizontal line is outputted, the solid-state imaging device cannot start/finish to accumulate the photo-generated charges of pixels on all horizontal lines simultaneously.

In order to solve such impediment, Japan Laid-Open Patent Publication (JP-A) No. 2002-134729 describes a MOS type solid-state imaging device that comprises an overflow drain region with a conductive type (n-type for instance) opposite to the charge generating region and the carrier pocket (p-type for instance). The overflow drain region serves as the potential burrier to the photo-generated charges. For the purpose of removing the photo-generated charges to the substrate, transfer gate electrodes are formed on the overflow drain region to control the potential burrier. Therefore, it is possible to start/finish to accumulate the photo-generated charges of whole pixels at the same time. That is, controlling the potential burrier works as a global electrical shutter.

Although the solid-state imaging device described in JP-A 2002-134729 can realize the global electrical shutter, providing and controlling the transfer gate electrodes and the gate electrodes of the MOS type transistor complicates the structure of each pixel and the imaging device. In addition, the above solid-state imaging device cannot start accumulation of photo-generated charges in the charge generation region while the image signal is detected. The field rate (fields/sec) in taking a moving image is not sufficient, because the above solid-state imaging device need to repeat the operations to start/finish to store the photo-generated charges and to detect the image signal alternately.

### SUMMARY OF THE INVENTION

An object of the present invention is to provide a solid-state imaging device with a simple structure of a global electrical shutter.

Another object of the present invention is to provide a solid-state imaging device capable of taking a still image and a moving image with high field rate.

Further object of the present invention is to provide a method of driving such solid-state imaging device as described above.

To achieve the above objects, the solid-state imaging device equipped with plural unit pixels each of which includes a photo-diode and a photo-detector on a substrate, the photo-diode comprising a charge generating region to generate charges upon light irradiation, the photo-detector comprising a charge accumulation region to accumulate the charges transferred from the charge generating region and generating a signal potential that changes in accordance with the amount of the charges in the charge accumulation region, and a charge transfer region provided between the charge generating region and the charge accumulation region of the pixel, the charge transfer region forming a first potential barrier to the charges in the charge generating region, the first potential barrier being removable according to the applied voltage to the photo-detector.

The charge generating region has one conductive type, same as the substrate, and the photo-diode comprises a first region with opposite conductive type that contacts the charge generating region. The photo-detector is a field effect transistor, and comprises a channel region formed on the surfaces of the charge accumulating region with one conductive type and the charge transfer region with opposite conductive type, a gate electrode formed on a gate insulation layer that is formed on the channel region, a source region having opposite conductive type, the source region near the charge accumulating region being connected to the channel region; and a drain region with opposite conductive type that is apart from the source region by the channel region, the signal potential being generated in the source region.

The plural pixels are arranged in first and second directions to form a matrix. The source regions of the pixels along the first direction are connected to one another, and the gate electrodes of the pixel along the second direction are connected to one another. The drain regions of all pixels are common.

The source region and the drain region of the pixel are electrically connected and disconnected by a switch circuit. A first charge eliminating region is formed between the substrate and the charge accumulating region. The charges in the charge accumulating region is eliminated to the substrate via the first charge eliminating region when the potentials of the charge accumulating region and the charge transfer region are increased by boosting up the voltage to the gate electrode. The voltage to the gate electrode is boosted by applying a voltage to the source and drain regions simultaneously while keeping the gate electrode at a high impedance state.

A second region with opposite conductive type is formed between the charge generating region and the second charge eliminating region with one conductive type. The second region forms a second potential barrier to the charges in the charge accumulating region, the second potential barrier is lower than the first potential barrier. Thereby, the charges in the charge eliminating region is overflowed to a surface side, opposite to the substrate, via the second charge eliminating region. The second potential barrier is removable according to the applied voltage to the second charge eliminating region.

The solid-state imaging device is preferably driven by the following steps. First, the first potential barrier in the charge transfer region is removed so as to transfer the charged from the charge generating region to the charge accumulating region. The charges in the charge accumulating region are eliminated to the substrate through the first charge eliminating region. The photo-generated charges are stored in the charge generating region for a predetermined period. Then, the first potential barrier is removed so as to transfer the charges from the charge generating region to the charge accumulating region.

Then, the signal potential (source potential) of the photo-detector is read out as the first signal potential. After eliminating the charges in the charge accumulating region to the substrate through the first charge eliminating region, the signal potential of the photo-detector is read out as the second signal potential. The image signal is obtained by subtracting the second signal potential from the first signal potential.

In capturing a moving image, the solid-state imaging device is preferably driven by the following steps. First, the first potential barrier is removed to transfer the charges from the charge generating region to the charge accumulating region. The signal potential of the photo-detector is read out as the first signal potential. After eliminating the charges in the charge accumulating region to the substrate through the first charge eliminating region, the signal potential of the photo-detector is read out as the second signal potential. The image signal is obtained by subtracting the second signal potential from the first signal potential. The second potential barrier of all pixels is removed to eliminate the charges in the charge generating region to the second charge eliminating region, while the image signal corresponding to the previous frame is outputted.

According to the present invention, since the solid-state imaging device can remove the potential barrier of the charge transfer region by controlling the application voltage to the photo-detector, it is possible to realize the global electrical shutter with a simple structure.

In addition, since photo-generated charges are eliminated to the surface of the imaging device through the second charge eliminating region, the imaging device can start accumulating the photo-generated charges for the second frame during the charges for the first frame are detected in the photo-detector. Thus, it is possible to take a moving image with high field rate.

Moreover, photo-generated charges in the charge accumulating region are removed to the surface side, not the substrate, of the pixel through the second charge eliminating region. Thus, it is possible to design and control the second potential barrier easily without regard to the potential of the substrate.

### BRIEF DESCRIPTION OF THE DRAWINGS

The above objects and advantages of the present invention will become easily understood by one of ordinary skill in the art when the following detailed description would be read in connection with the accompanying drawings, in which:

FIG. 1 is a plan view showing the layout of a unit pixel of a solid state imaging device according to the present invention;

FIG. 2 is a cross section showing the structure of the unit pixel, taken along the line A—A of FIG. 1;

FIG. 3 is a plan view showing the two-dimensional arrangement of the pixels;

FIG. 4 is a circuit diagram of the solid-state imaging device;

FIG. 5 is a flow chart of the image capture operation of the solid-state imaging device;

FIG. 6 is a timing chart of the applied voltages during the transfer and elimination periods;

FIG. 7 is a timing chart of the applied voltages during the accumulation and transfer periods;

FIG. 8 is a timing chart of the applied voltages during the horizontal blanking period;

FIG. 9 is a timing chart of the applied voltages during the horizontal scan period;

FIG. 10 is a cross section of the pixel to illustrate a hole channel;

FIG. 11 is a potential profile along the cross section taken on line B—B of FIG. 10 during the transfer and elimination periods;

FIG. 12 is a potential profile, similar to FIG. 11, during the accumulation and transfer periods;

FIG. 13 is a potential profile, similar to FIG. 11, during the readout period at the time when the photo-generated holes are accumulated in the hole pocket;

FIG. 14 is a potential profile, similar to FIG. 11, during the elimination period;

FIG. 15 is a potential profile, similar to FIG. 11, during the readout period when the photo-generated holes are ejected out of the hole pocket;

FIG. 16 is a potential profile, similar to FIG. 11, in capturing a moving image; and

FIGS. 17A, 17B, 18A, 18B, 19A, 19B, 20A, 20B, 21A, 21B and 22 are cross sectional views showing the processes to fabricate the pixel.

### PREFERRED EMBODIMENTS OF THE INVENTION

The embodiment of the present invention is described in detail hereinafter with reference to the accompanying drawings.

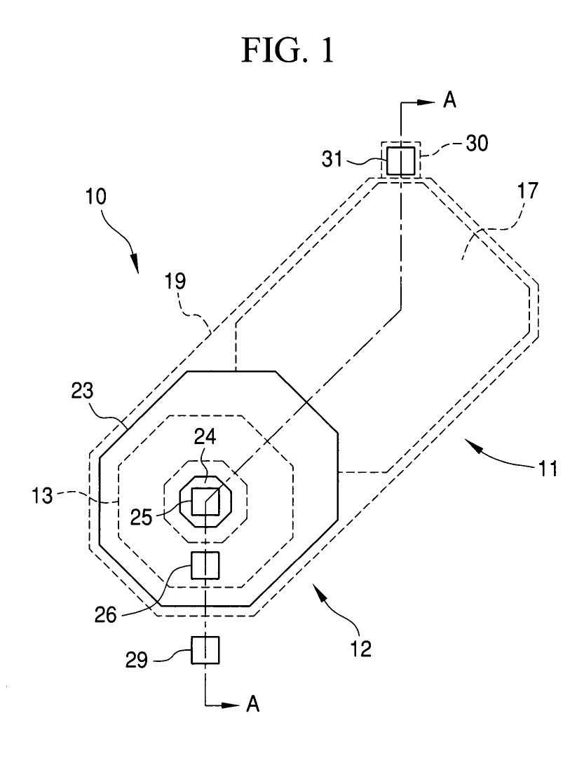

In FIG. 1 that shows a layout of a unit pixel of the solid-state imaging device, the pixel 10 includes a photo-diode 11 and a photo-detector 12. The photo-diode 11 serves as a region to generate charges by light illumination. The photo-detector 12 is a MOS type transistor coupled to the photo-diode 11, and the threshold voltage (source potential) thereof is modulated in accordance with the potential caused by the holes in a hole pocket 13 that is formed below the channel region of the photo-detector 12. The image signals are obtained by detecting the source potential.

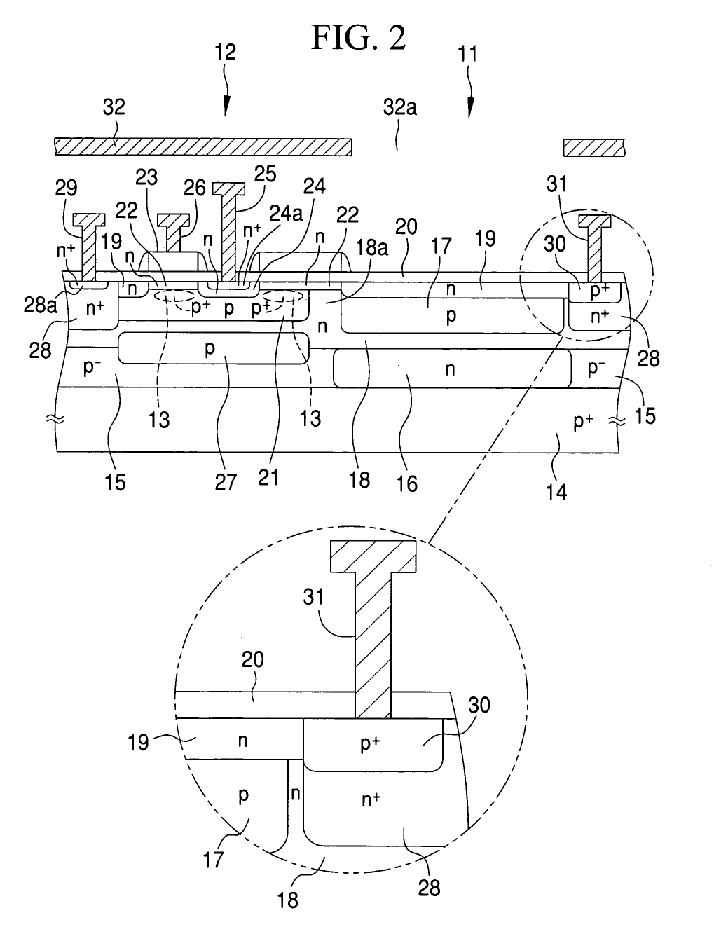

As shown in FIG. 2, a semiconductor substrate 14 is p⁺-type silicon in which p-type (one conductive type) impurities are highly doped. An epitaxial layer 15 on the substrate 14 is formed from p⁻-type silicon with lower impurity density than the substrate 14. The photo-diodes 11, the photo-detectors 12 and driver circuits (not illustrated) are formed on the substrate 14.

The photo-diode 11 comprises an n-type (opposite conductive type) buried layer 16 in the epitaxial layer 15, a p-type charge generating region 17 on the buried layer 16, an n-type layer 18, and an n-type impurity region 19 covering the surface of the charge generating region 17. The n-type layer 18 is so formed on the epitaxial layer 15 as to surround the charge generating region 17 and contact the surface of the buried layer 16. An insulation film 20 is formed on the surface of the n-type impurity region 19. Thus, the photo-diode 11 constitutes an npn structure. The n-type buried layer 16 serves as a deep depletion layer in the charge generating region 17, and therefore, it is possible to increase the sensitivity to red light (long wavelength light) that excites charges in a deep region from the surface of the photo-diode 11.

The n-type layer 18 on the epitaxial layer 15 extends from the photo-diode 11 to the photo-detector 12. On the n-type layer 18 of the photo-detector 12 side, there is a p-type well region 21 to which the photo-generated charges in the charge generating region 17 is transferred. The hole pocket 13 is a p⁺-type region with highest impurity density in the p-type well region 21. The hole pocket 13 and the p-type well region 21 constitutes the charge accumulation region, and the photo-generated charges from the photo-diode 11 to the p-type well region 21 is accumulated in the hole pocket 13. The n-type layer 18 is extended to the region between the charge generating region 17 and the p-type well region 21 to form a charge transfer region 18a. It is possible to remove the potential in the charge transfer region 18a by controlling the applied voltage to the photo-detector 12. Thus, the potential in the charge transfer region 18a can control the transfer of the holes from the charge generating region 17 to the hole pocket 13.

On the surface of the hole pocket 13 and the charge transfer region 18a, an n-type channel dope layer (channel region) 22 is formed. A gate electrode 23, formed on the channel dope layer 22 via the insulation layer 20, is in the shape of non-symmetric octagonal and hollowed ring (see FIG. 1). The channel dope layer 22 is connected to an n-type source region 24 that is provided in the middle portion of the p-type well region 21 surrounded by the ring-shaped gate electrode 23. In forming the source region 24 by introduction of n-type impurities in the p-well region 21, the p-type impurities in the p-well region 21 is re-distributed such that the impurity density in the area masked by the gate electrode 23 is increased to form the hole pocket 13. When the gate electrode 23 is biased, the channel dope layer 22 is filled with electrons (so-called pinning state) to decrease the dark current (hole charges) in the interface between the channel dope layer 22 and the insulation layer 20.

There is an n⁺-type contact layer 24a on the surface of the source region 24. A plug 25 and a plug 26 are respectively connected to the contact layer 24a and the gate electrode 23.

Below the p-type well region 21, a p-type buried layer 27 with relatively high impurity density is embedded via the n-type layer 18. The n-type layer 18 becomes thin in the area below the p-well region 21. The impurity distribution in the p-type buried layer 27 and the n-type layer 18 is designed such that the depletion layer extends in the p-type well region 21, not in the p-type buried layer 27, in ejecting holes to the substrate 14 via the p-type buried layer 27. The depletion layer extended in the p-type buried layer 27 is thin. Since the electric field is concentrated in the p-well region 21 in ejecting holes to the substrate 14, rapid change in the potential is generated in the p-type well region 21 with low reset voltage. Therefore, it is possible to ensure to eject the photo-generated holes accumulated in the hole pocket 13.

The n-type impurity region 19 in the photo-diode 11 surrounds the photo-detector 12, and serves as the drain region of the photo-detector 12 by contacting the channel dope layer 22. That is, the cathode region of the photo-diode 11 and the drain region of the photo-detector 12 are common. An n⁺-type impurity region 28 connects the outer side of the n-type impurity region 19 so that the drain region of the photo-detector 12 is extended. A plug 29 is coupled to an n⁺-type contact layer 28a that is formed on the surface of the n⁺-type impurity region 28 in the photo-detector 12 side. An voltage is applied to the drain region of the photo-detector 12. A p⁺-type impurity region (charge elimination region) 30 is formed on the surface of the n⁺-type impurity region 28 in the photo-diode 11 side. The p⁺-type impurity region 30 is connected to a plug 31.

As shown in the enlarged view of FIG. 2, there is a small gap of the n-type layer 18 between the p⁺-type impurity region 30 and the charge generating region 17. The n-type layer 18 in the small gap serves as a potential barrier (PB) to the photo-generated holes in the charge generating region 17. When strong light is illuminated in the charge generating region 17, photo-generated holes are overflowed to pass over the potential barrier, and eliminated outside via the p⁺-type impurity region 30 and the plug 31. The p⁺-type impurity region 30 is called a lateral overflow drain region (LOD) to the photo-generated holes to prevent the photo-generated holes from being overflowed to the adjacent pixel, and therefore, it is possible to prevent blooming.

Each pixel 10 is covered by a metal layer (light-shielding film) 32 in light-tight manner, except the area in which a light-illumination window 32a is formed above the photo-diode 11.

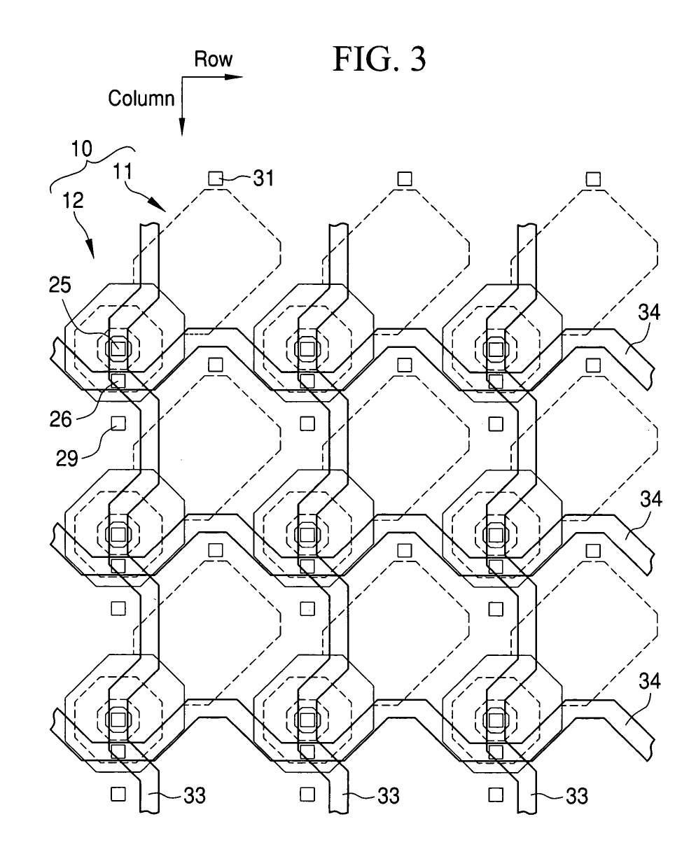

Referring to FIG. 3, the light receiving section is comprised of two-dimensional array of the pixels 10 arranged in rows and columns such that the n⁺-type impurity regions 28 of the pixels 10 are coupled. The plugs 25 coupled to the source regions 24 are connected to one another via plural vertical output line 33. One vertical output line 33 connects the plugs 25 of one column (arranged in the first direction). The plugs 26 coupled to the gate electrodes 23 of the photo-detectors 12 are connected to one another via plural vertical scan signal transfer lines 34. One vertical scan signal transfer line 34 connects the plugs 26 of one row (arranged in the second direction). The vertical output line 33 and the vertical scan signal transfer line 34 are different metal layers. The plugs 29 connected to the drain regions of the photo-detectors 12 are coupled via drain voltage supply lines 35 that extends in the first or the second direction. The plugs 31 electrically connected to the lateral overflow drain regions of the photo-diodes 11 are coupled to one another via common lines.

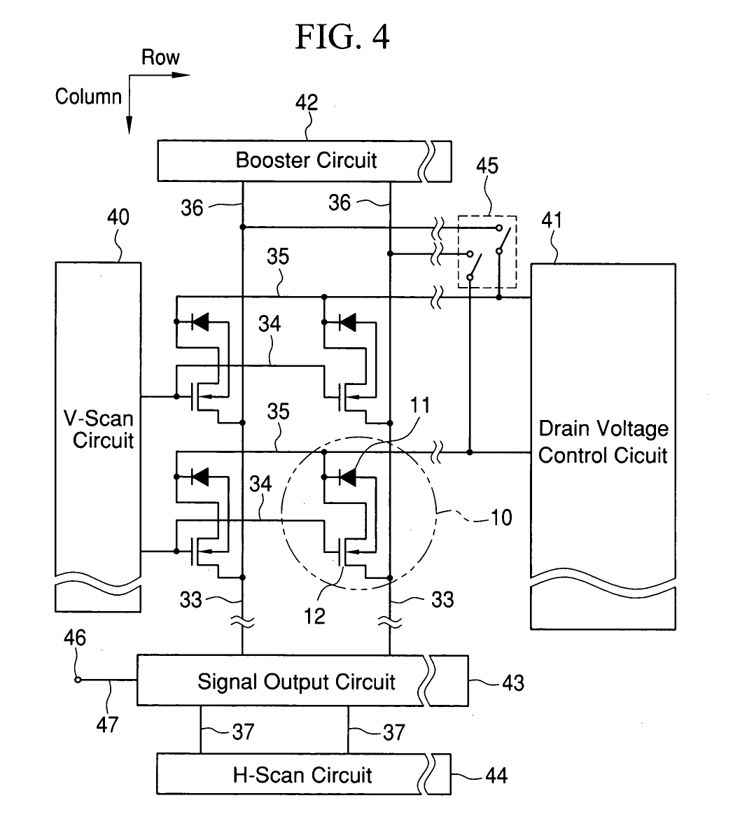

Referring to FIG. 4, the MOS type solid-state imaging device has plural circuits, such as a vertical scan (V-scan) circuit 40, a drain voltage control circuit 41, a booster circuit 42 for source potential, a signal output circuit 43, a horizontal scan (H-scan) circuit 44 and a switch circuit 45. These circuits are connected to the plural pixels 10. In the example shown in FIG. 4, the imaging device comprises a 2×2 matrix for the purpose of simplicity. The lines to connect the lateral overflow drain regions are not illustrated in order to simplify the drawing. The switch circuit 45 connects and disconnects the source regions and the drain regions of the photo-detectors 12. It is possible to utilize the circuit described in FIG. 2 of U.S. Pat. No. 5,335,015, for instance, as the switch circuit 45.

The V-scan circuit 40 sends vertical scan signals to the gate electrodes 23 of the photo-detectors 12 via the vertical scan signal lines 34. The drain voltage control circuit 41 supplies the common drain voltage to the drain regions of the photo-detectors 12 via the drain voltage supply lines 35. The booster circuit 42 is coupled to the boosted voltage output lines 36, each of which is connected to each of the vertical output lines 33. The switch circuit 45 connects and disconnects the drain potential output line 35 to the boosted voltage output line 36 of each pixel 10, so that the source region and the drain region of the photo-detector 12 are electrically connected and disconnected. When the booster circuit 42 boosts up the source potential to be applied to the source region 24 via the boosted voltage output lines 36, and when the switch circuit 45 connects the source region and the drain region of the photo-detector 12, the common boosted voltage is applied to the source region and the drain region at the same time.

The signal output circuit 43, connected to the vertical output lines 33, has first line memories, second line memories and a noise reduction circuit. The pair of the first and second line memories is provided for each of the vertical output lines 33. The first line memory stores the potential information of the source region 24 (VoutS). The potential information VoutS includes the potential modulated by the holes accumulated in the hole pocket 13, and the standard potential original to the pixel 10 before hole accumulation. The second line memory stores the potential information of the source region (VoutN) that consists of the above standard potential after eliminating the photo-generated holed out of the hole pocket 13. The noise reduction circuit serves as a difference circuit that calculates the light detection signal (Vout) as the image signal caused by the holes accumulated in the hole pocket 13, according to the equation (Vout=VoutS−VoutN).

The H-scan circuit 44 is connected to the signal output circuit 43 via the horizontal scan lines 37. Each of the horizontal scan lines 37, provided for each row of the pixels 10, is connected to a switch (not illustrated) to select the first line memory or the second line memory of the signal output circuit 43. The H-scan circuit 44 outputs the horizontal scan signals (HSCAN) to the horizontal scan lines 37 to scan the first and second line memories for each pixels 10. The signal output circuit 43 is connected to an output terminal via an output line 47 for outputting the light detection signals (Vout).

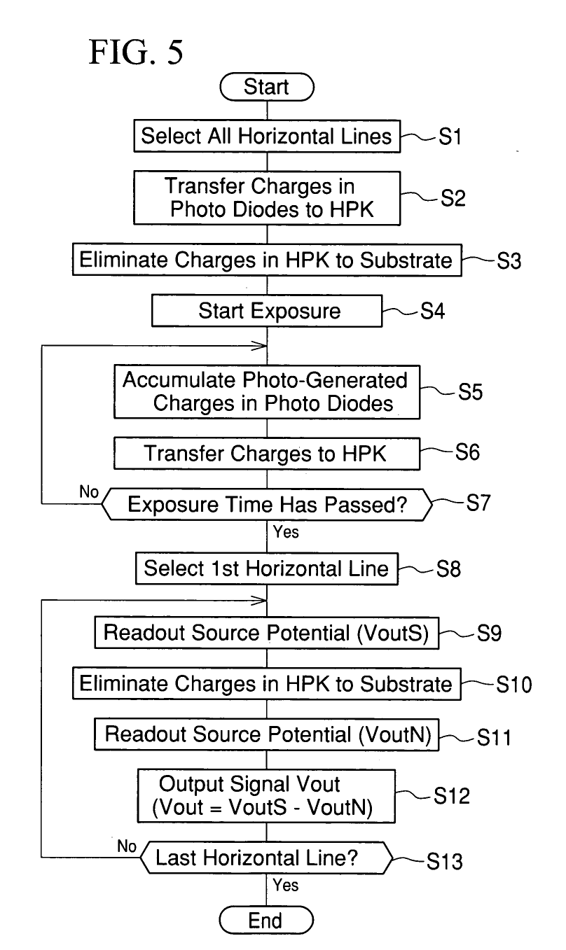

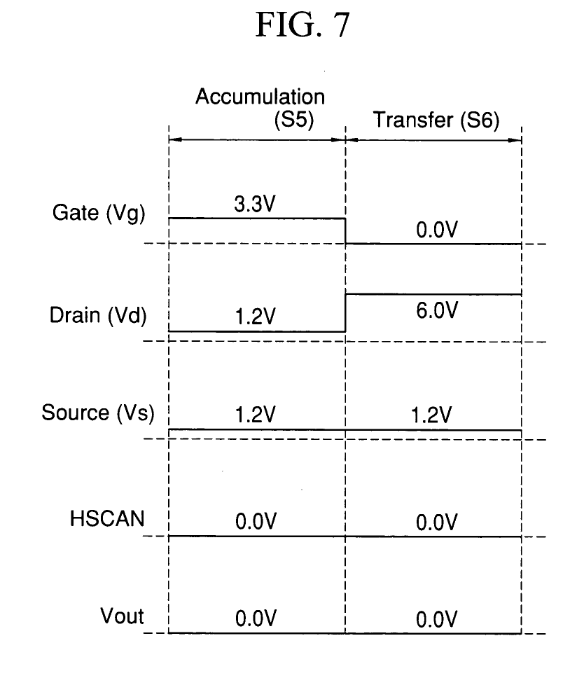

The operation of the MOS type solid-state imaging device will be described with reference to FIGS. 5-15. Note that the pixels 10 are arranged in rows and columns (see FIGS. 3 and 4), and that the line in the row direction is called as a horizontal line. The gate electrodes 25 of the pixels 10 on the same horizontal line are connected via the vertical scan signal transfer lines 34. The horizontal line is selected and scanned by the V-scan circuit 40.

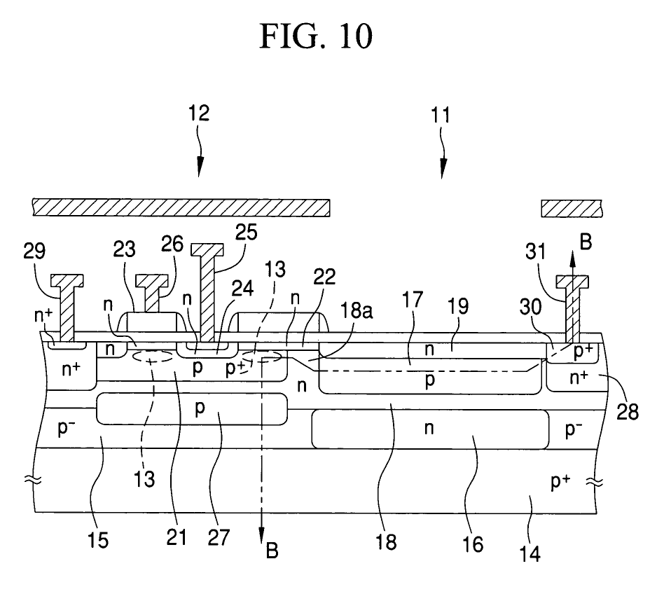

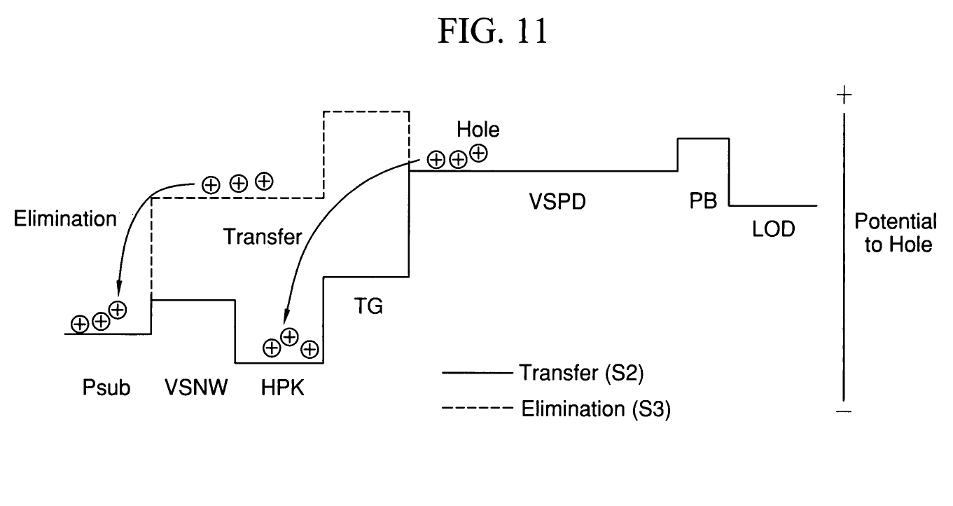

Referring to FIG. 5, all horizontal lines are selected upon starting the image capture operation the MOS type solid-state imaging device (S1). The photo-generated charges (holes) in the charge generating regions 17 of the photo-diodes 11 are transferred to the hole pockets (HPK) 13 (S2). In order to transfer the photo-generated charges to the hole pockets 13, the gate voltage Vg of 0.0V, the drain voltage Vd of 6.0V and the source voltage Vs of 1.2V are applied to all pixels 10 at the same time. The potential profile to the holes along the line B-B of FIG. 10 during this step is shown in FIG. 11 by the solid line. The line B−-B of FIG. 10 passes the p⁺-type impurity region (LOD) 30, the n-type layer (PB) 18, the charge generating region (VSPD) 17, the transfer region (TG) 18a, the hole pocket (HPK) 13, the n-type layer (VSNW) 18 and the substrate (Psub) 14 in this order listed. As shown in FIG. 11, the potential of the transfer region 18a becomes lower than that of the charge generating region 17 so that the holes in the charge generating region 17 is transferred to the hole pocket 13 with lower potential than the charge generating region 17. Such charge transfer step is carried out to all pixels 10 at the same time.

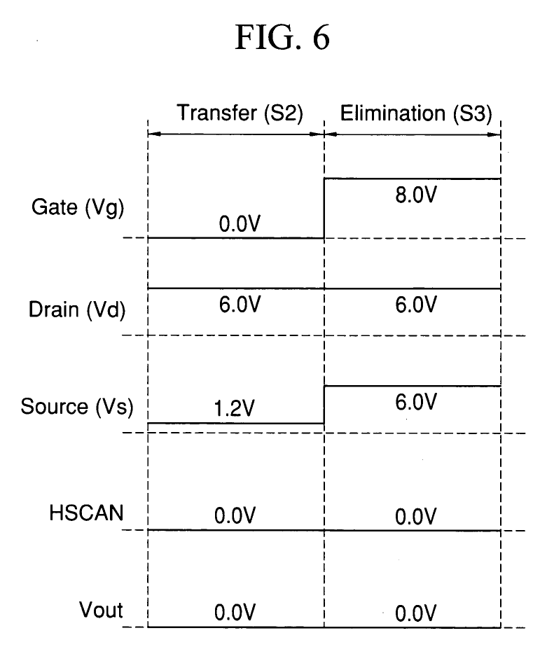

After transferring the photo-generated holes from the photo-diodes 11 to the hole pockets 13, the holes in the hole pockets 13 are eliminated to the substrate 14 (S3). At this step, the gate voltage Vg of 8.0V, the drain voltage Vd of 6.0V and the source voltage Vs of 6.0V are applied to all pixels 10 at the same time (see FIG. 6). It is possible to boost the gate voltage Vg up to 8.0V by keeping the high-impedance state (disconnect the gate electrode 25 from an external circuit) after increasing the gate potential Vg to 2.0V, driving the switch circuit 45 to connect the source region and the drain region, and driving the booster circuit 42 to increase the source and gate potentials into 6.0V. Then, as shown in the broken lines of FIG. 11, the potential of the transfer region 18a is increased. Moreover, the potential of the carrier pocket 13 becomes substantially the same as that of the n-type layer 18, so that the holes accumulated in the hole pocket 13 moves to the substrate 14 with lower potential than the hole pocket 13. Such elimination step is carried out all pixels 10 at the same time.

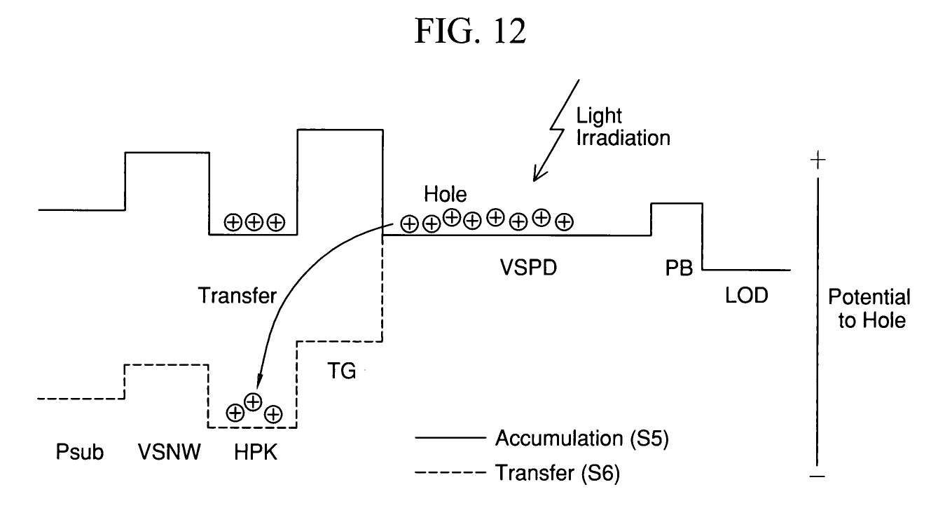

During the above described steps S2, S3, the holes in the carrier generating region 17 are eliminated (swept) to the substrate 14 prior to the exposure. Then, the solid-state imaging device starts the exposure (S4), and accumulates the photo-generated holes in the charge generating regions 17 (S5). Note that the step S4 stands for stating generation and accumulation of the holes by light irradiation after ejecting the holes out of the charge generating region 17, not after driving the mechanical shutter of the camera. During the accumulation step S5, the gate voltage Vg of 3.3V, the drain voltage Vd of 1.2V and the source voltage Vs of 1.2V are applied to all pixels 10 at the same time (see FIG. 6). As shown in the solid lines of FIG. 12, the potential of the transfer region 18a increases and works as the potential barrier between the charge generating region 17 and the hole pocket 13. Therefore, the photo-generated holes are accumulated in the charge generating region 17. Such accumulation step is carried out in all pixels 10 at the same time.

After predetermined time of accumulation, the photo-generated holes in the charge generating region 17 is transferred to the hole pocket (S6). The transfer step is carried out in all pixels 10 at the same time. The application voltages to the source, drain and gate regions and the potential profile are the same as those in the transfer step (S2) described above, so the detailed description is omitted. After the transfer step S6, the elapsed time after stating the exposure is detected (S7). If the predetermined exposure time has not elapsed, the accumulation step S5 and the transfer step S6 are repeated until the exposure time has passed. The exposure time corresponds to the shutter-open time (shutter speed) of ordinary cameras.

The photo-generated holes are transferred to the hole pocket 13 by repeating the accumulation step S5 and the transfer step S6, because the capacitance of the charge generating region 17 becomes smaller than that of the hole pocket 13 due to the miniaturization of the pixel 10. Thus, it is necessary to divide the charge accumulation time. The period for each accumulation time may be decided accordingly. In addition, the pinning state in the channel dope layer 22 stops during the transfer step S6 by changing the gate voltage Vg into 0.0V. Carrying out the transfer step S6 after the accumulation step S5 makes it possible to shorten the practical transfer period, and therefore to decrease the amount of the dark current.

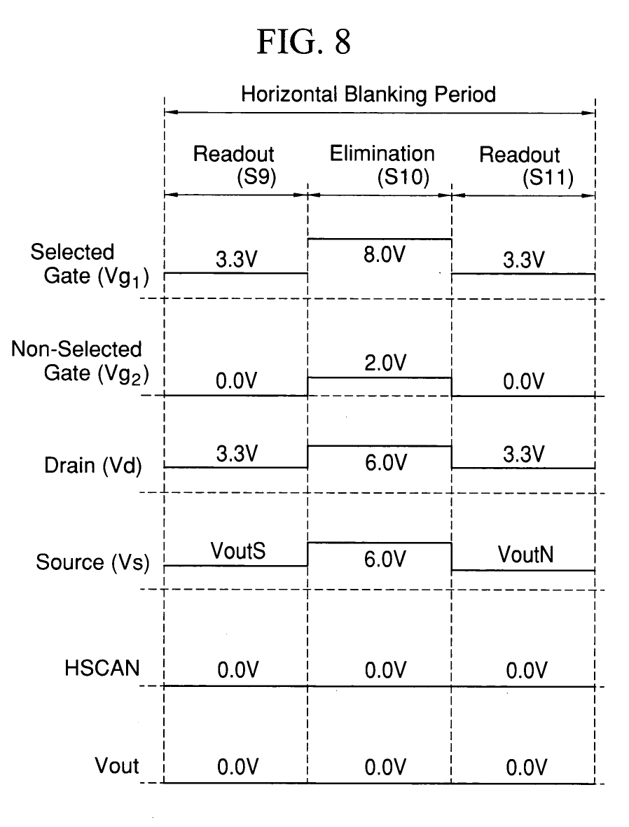

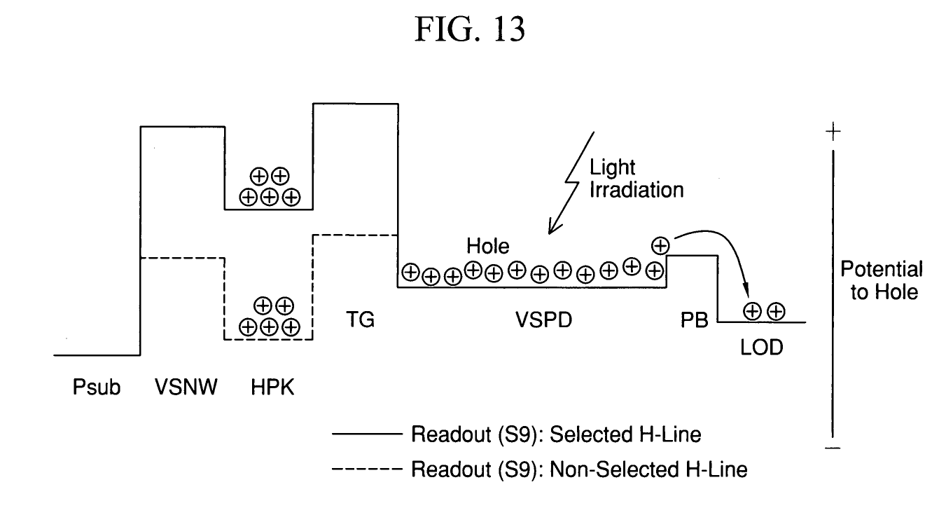

When the predetermined exposure time has passed, the V-scan circuit 40 selects the first horizontal line (S8). Then, the source potentials (VoutS) of the pixels 10 on the selected horizontal line are read out and the source potential information is stored in the first line memories of the signal output circuit 43 (S9). The source potential VoutS includes the potential modulated by the photo-generated holes in the carrier pocket 13 and the standard potential of the pixel 10. In FIG. 8, the gate voltage Vg1 of 3.3V is applied to the pixels 10 on the selected horizontal line, whereas the gate voltage Vg2 to the pixels 10 on the non-selected horizontal line is 0.0V. In FIG. 13, the potential profile of the pixels 10 on the selected line is shown by solid lines, and the potential profile of the pixels 10 on the non-selected line is shown by broken lines. The potential profile in FIG. 13 shows that the potential of the hole pockets 13 of the pixels 10 on both selected and non-selected lines becomes lower than the potentials of the surrounding regions. In addition, a potential barrier is formed between the transfer region 18a and the charge generating region 17, and therefore, the photo-generated holes transferred to the hole pocket 13 according to step S6 do not move to other regions.

During the readout step to detect the source potential VoutS, the charge generating region 17 continues to generate the photo-generated holes by light irradiation to the photo-diode 11. The potential barrier (PB) of the n-type layer 18 is lower than the potential barrier of the transfer region 18a. Thus, if the amount of the photo-generated holes exceeds the capacity of the charge generating region 17, the overflowed photo-generated holes are eliminated to the lateral overflow drain region (LOD) in the P⁺-type impurity region 30 via the potential barrier (PB) of the transfer region 18a. Thereby, it is possible to prevent the overflowed holes from being transferred to the hole pocket 13 or adjacent pixels 10.

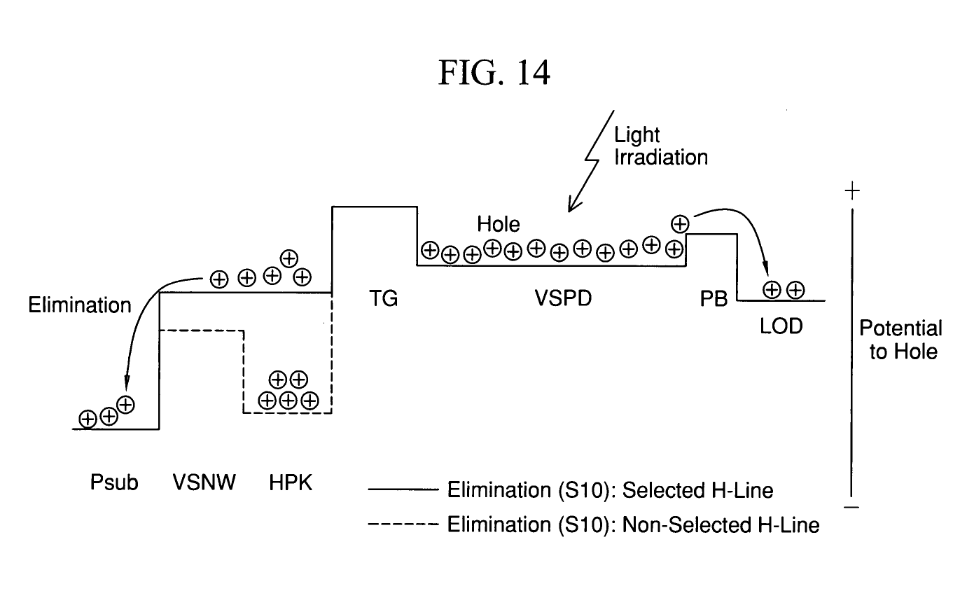

After reading out the source potential (VoutS), the photo-generated holes in the pixels 10 on the selected horizontal line is eliminated to the substrate 14 (S10). In this step, the gate voltage Vg1 to the pixels 10 on the selected horizontal line is 8.0V (the same as the gate voltage in step S3), whereas the gate voltage Vg2 to the pixels 10 on the non-selected horizontal lines is 2.0V. In FIG. 13, the potential profile of the pixels 10 on the selected line is shown by solid lines, and the potential profile of the pixels 10 on the non-selected line is shown by broken lines. FIG. 14 shows that the photo-generated holes in the carrier pocket 13 are ejected in the pixels 10 on the selected horizontal line, and that the photo-generated holes in the carrier pocket 13 are not ejected in the pixels 10 on the non-selected horizontal line. During the hole elimination step S10, the charge generating region 17 continues to generate the photo-generated holes by light irradiation. Overflowed photo-generated holes are eliminated to the surface of the pixel 10 through the lateral overflow drain region (LOD).

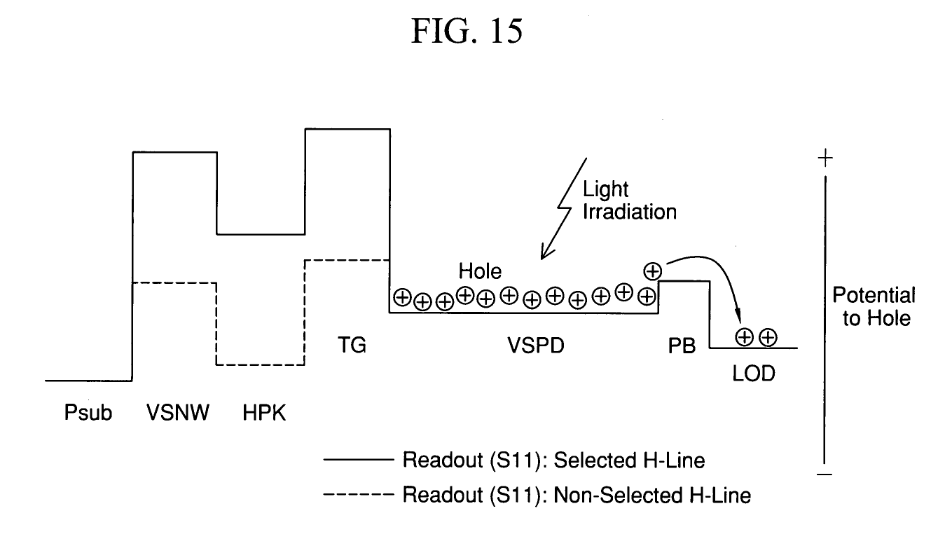

When the holes in the hole pockets 13 are eliminated, the source potentials VoutN in the pixels 10 on the selected horizontal line are read out, and the potential information is stored in the second line memories of the signal output circuit 43 (S11). The source potential VoutN consists of the standard potential of each pixel 10. The applied voltages to the pixels 10 are the same as those in the step S9, as shown in FIG. 8. The potential profile in this step S11 is shown in FIG. 15. The steps S9-S11 are carried out in the horizontal blanking period.

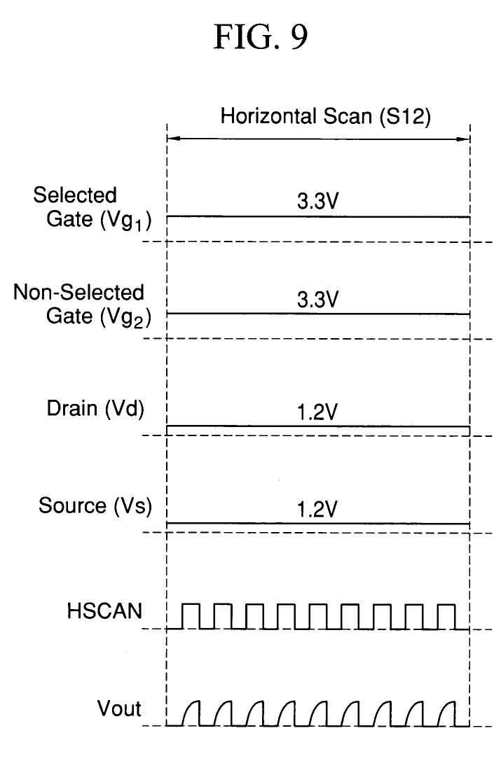

After the horizontal blanking period, the H-scan circuit 44 scans the potential data in the first and second line memories for each row, and then the noise reduction circuit calculates the difference in the potential, according to the equation (Vout=VoutS−VoutN). The potential difference Vout for each pixel, as the light detection signal, is sequentially output to the output terminal 46. As shown in FIG. 9, the light-detection signals are sequentially output in synchronization with the horizontal scan signals (HSCAN). In the output step S12, the same voltages as those in the accumulation step S5 are applied to each pixel, so the photo-generated holes are retained in the hole pockets 13 of the pixels 10 on the non-selected horizontal line.

When the steps S9-S12 are completed for the first horizontal line, the pixels 10 on the second horizontal line are subject to the same steps S9-S12. In this way, the same light detection signals of the pixels 10 of the all horizontal lines are outputted. When the steps S9-S12 for the last horizontal line are completed (S13), the image signals of the still image are obtained. The solid-state imaging device can continue to capture the image of the second frame by carrying out the first step S1 and repeating the same steps S1-S13.

During the steps S1-S13, the switch circuit 45 is driven to connect and disconnect to supply the gate voltage Vg, drain voltage Vd and source voltage Vs in each step. As shown in FIGS. 6-9, the drain voltage Vd is the same as the source voltage Vs in the elimination steps S3, S10, accumulation step S5 and horizontal scan step S12. On the other hand, the drain voltage Vd is different from the source voltage Vs in the transfer steps S2, S6 and the readout steps S9, S11.

The switch circuit 45 electrically connects the drain voltage supply line 35 and the vertical output line 33 at the steps S3, S5, S10 and S12, and disconnects them at the steps S2, S6, S9 and S11. In other words, the switch circuit 45 connects the drain voltage supply line 35 and the vertical output line 33 at the steps other than the transfer steps (S2, S6) and the readout steps (S9, S11). The switch circuit 45 adjusts the timing to start connect/disconnect operations for the purpose of transferring the photo-generated charges at each step.

According to the description above, the solid-state imaging device with the global electrical shutter can capture a still image. Next, the operation to capture a moving image will be described.

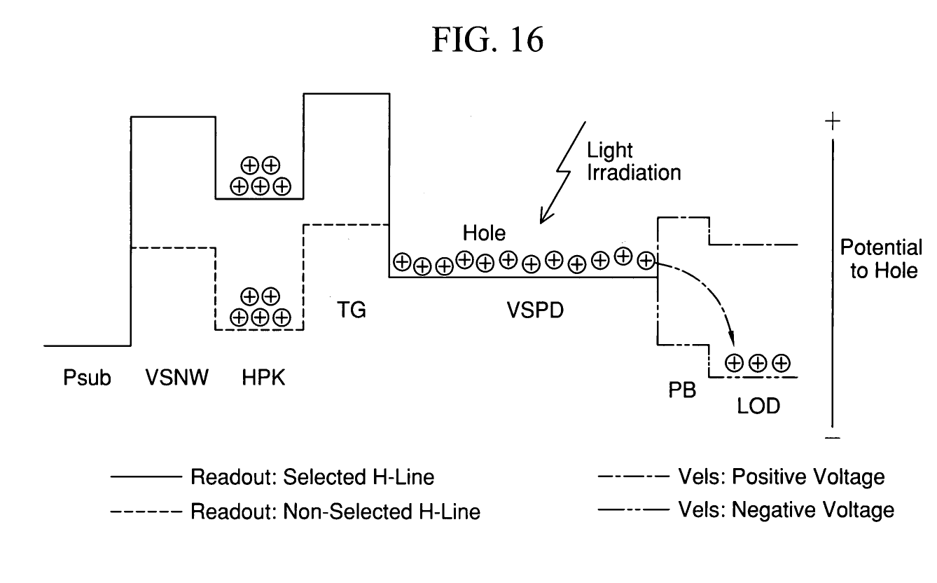

As shown in FIG. 16, the potential of the p⁺-type impurity region 30 as the lateral overflow drain region (LOD) is changed by applying the voltage Vels to the p⁺-type impurity region 30 through the plug 31. When the voltage Vels in the above detection step is negative (−5.0V, for instance), the potential barrier (PB) and the potential of the p⁺-type impurity region 30 decrease so that the photo-generated holes accumulated in the charge generating region 17 are eliminated to the p⁺-type impurity region 30. On the other hand, when the voltage Vels is positive (3.3V for instance), the potential barrier (PB) and the potential of the p⁺-type impurity region 30 increases so that the photo-generated holes are kept in the charge generating region 17.

Controlling the applied voltage Vels to the lateral overflow drain region makes it possible to carry out the steps S1-S3 (elimination of the holes) during the steps S9-S12. The solid-state imaging device can start the exposure (accumulating the photo-generated holes) of the next frame during the steps S9-S12 for the previous frame. Accordingly, it is possible to increase the field rate (the number of captured frames per second) in capturing the moving image. It is also possible to change the exposure time.

Therefore, the global electrical shutter of the solid-state imaging device according to the embodiment can exposure all the pixels 10 at the same time and control the exposure time (shutter speed).

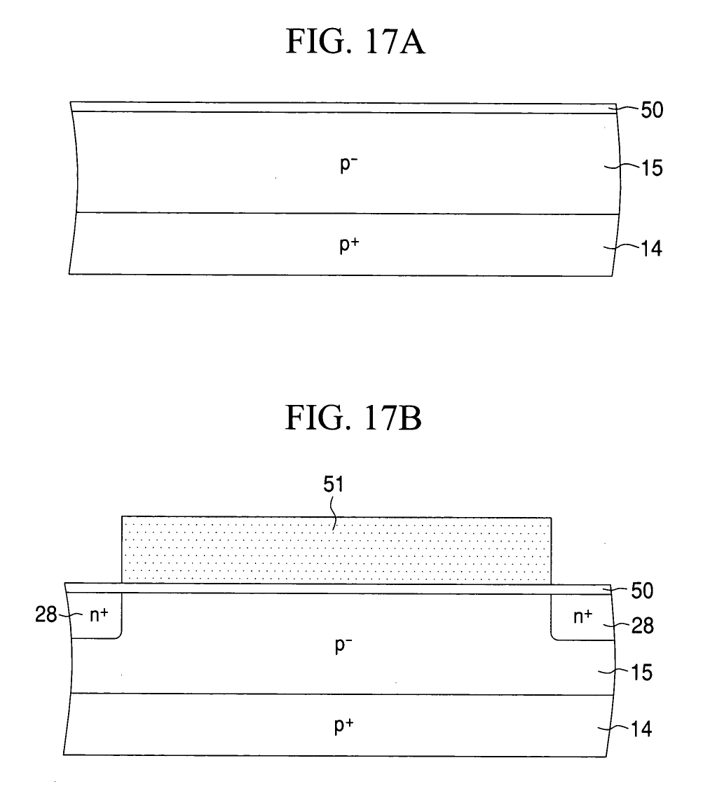

Next, the processes to fabricate the pixel 10 will be described with reference to the drawings. In FIG. 17A, p⁻-type silicon with the lower impurity than the p⁺-type substrate 14 is epitaxially deposited on the substrate 14, so that the p⁻-type epitaxial layer 15 with the impurity density of about 1.0×10¹⁵ cm⁻³ is formed. Then, the insulation layer 50 is generated by thermal oxidization of the surface of the p⁻-type epitaxial layer 15.

As shown in FIG. 17B, a resist mask 51 is overlaid on insulation layer to cover the pixel region. Then, n-type impurity ions (Phosphorus⁺(Ph⁺)) are implanted by ion implantation process. Thereby, the n⁺-type impurity region 28 with relatively high impurity density is formed in the surface of the p⁻type epitaxial layer 15 that are not covered with the resist mask 51.

After removing the resist mask 51, a resist mask 52 with the opening 52a corresponding to the photo-diode 11 is formed, and then the n-type impurity ions (Ph⁺) are deeply implanted through the opening 52a. Thereby, n-type buried layer 16 with the peak impurity density of about 1.0×10¹⁷ cm⁻³ is formed in a bottom region of the p⁻-type epitaxial layer 15. In addition, a p-type well layer 53 with the peak impurity density of about 6.0×10¹⁶ cm⁻³ is formed in the surface of the p⁻-type epitaxial layer 15 by implanting the p-type impurity ions (Boron⁺(B⁺)) in a shallow region. Informing the p-type well layer 53, a small gap is formed between the p-type well layer 53 and the n⁺-type impurity region 28.

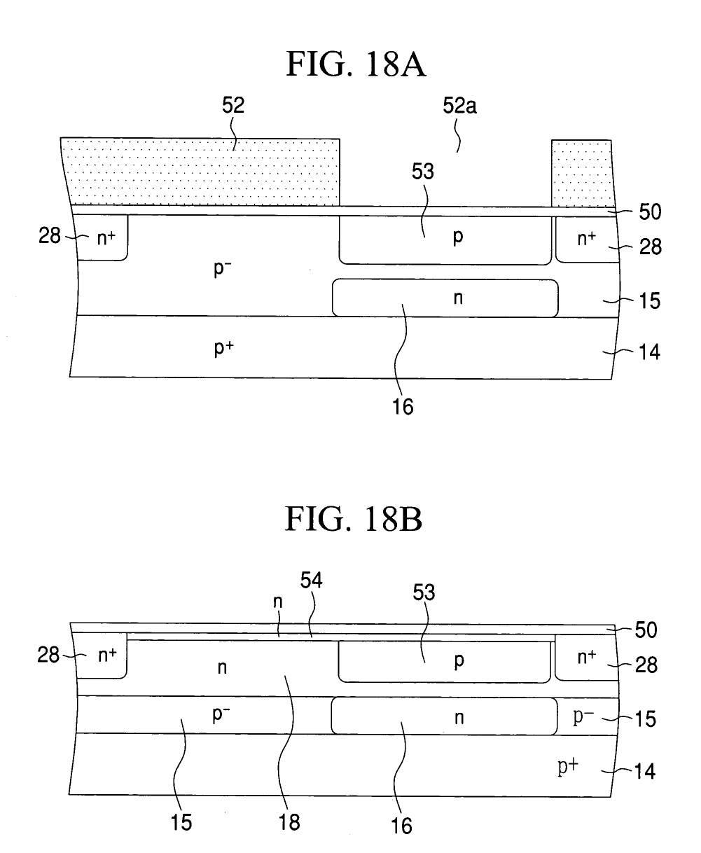

After the resist mask 52 is removed, n-type impurity ions (Ph⁺) are implanted in the whole area, the n-type layer 18 with the peak impurity density of about 3.0×10¹⁶ cm⁻³ is formed in the whole surface of the p⁻-type epitaxial layer 15, as shown in FIG. 18B. Thereafter, n-type impurity ions (Arsenic⁺(As⁺)) are implanted in the whole area of the n-type layer 18 so that the n-type dope layer 54 with the impurity density of about 2.0×10¹⁷ cm⁻³ is formed in the shallow region of the p-type well layer 53 and the n-type layer 18.

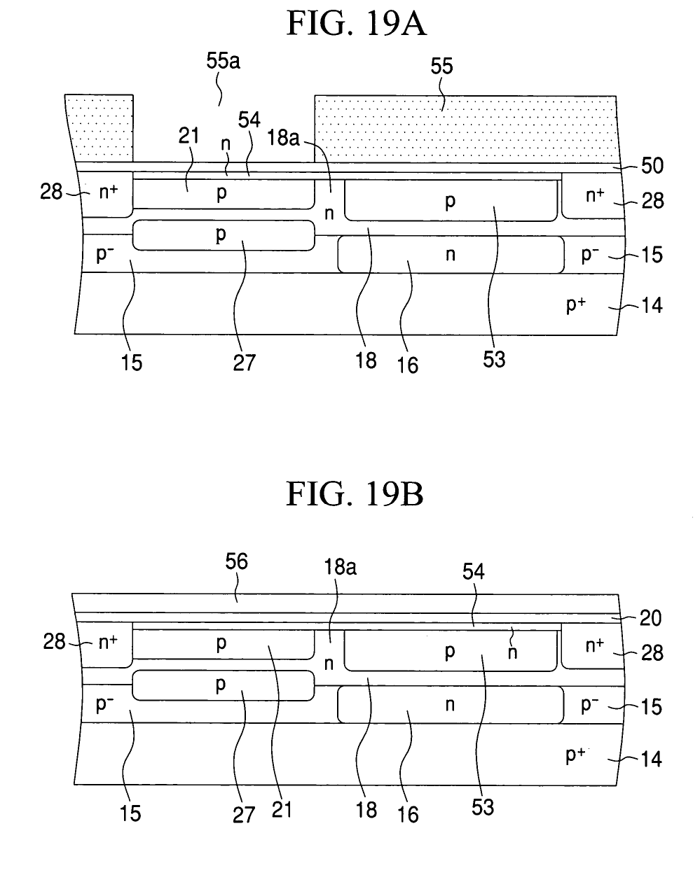

As shown in FIG. 19A, a resist mask 55 with the opening 55a corresponding to the photo-detector 12 is formed, and then the n-type impurity ions (B⁺) are deeply implanted through the opening 55a. Thereby, p-type buried layer 27 with the peak impurity density of about 5.0×10¹⁶ cm⁻³ is formed in a deep region that is connected to the p⁻-type epitaxial layer 15. In addition, a p-type well layer 21 with the peak impurity density of 6.0×10¹⁶ cm⁻³ is formed in the surface of the n-type layer 18 by shallowly implanting the p-type impurity ions (Boron⁺(B⁺)) through the opening 55a. The n-type layer 18 becomes thinner in the area between the p-type buried layer 27 and the p-type well region 21 than other area thereof. In addition, the n-type layer 18 partially remains between the p-well region 21 and the p-type well layer 53 to form the above described transfer region 18a.

The resist mask 55 and the insulation film 50 are removed. Then, the surface of the pixel is subject to thermal oxidization to form the insulation film 20 (see FIG. 19B). The conductive film 56 is formed on the insulation film 20 by depositing poly silicon and tungsten silicide, for instance.

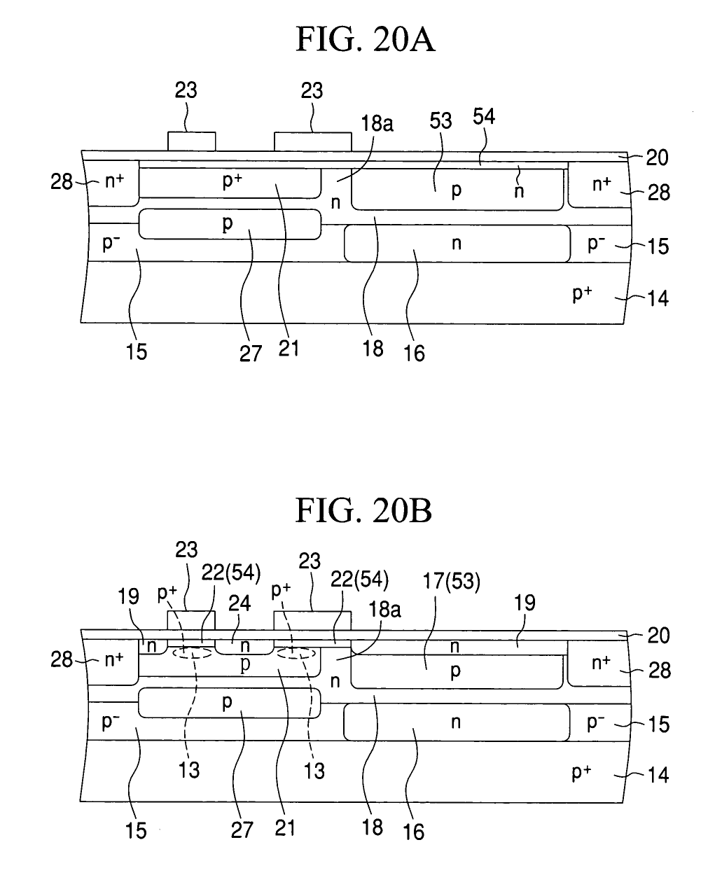

As shown in FIG. 20A, the conductive film 56 is subject to patterning process by etching to form the gate electrode 23 of the photo-detector 12. The ring-shaped gate electrode 23 is formed on the p-type well region 21 and covers the transfer region 18a.

The n-type impurity region 19 and the source region 24 with the impurity density of 6.0×10¹⁷ cm⁻³ are formed by shallowly implanting the n-type impurity ions (As⁺) via the gate electrode 23 as a mask, as shown in FIG. 20B. Such ion injection changes the impurity distribution in the p-type well region 21 such that the density in impurities near the gate electrode 23 increases whereas the density in other area decreases. After the ion implantation, the thin n-type dope layer 54 is localized in the area below the gate electrode 23, thereby the channel dope layer 22 is formed. In the p-type well region 12 below the channel dope layer 22, a high impurity density region as the hole pocket 13 is formed by self-alignment to the gate and source electrodes 23, 24. The p-type well layer 53, the n-type impurity region 19 and the n-type layer 18 constitutes the npn-type photo diode. The p-type well layer 53 is the anode (charge generating region 17) of the photo diode.

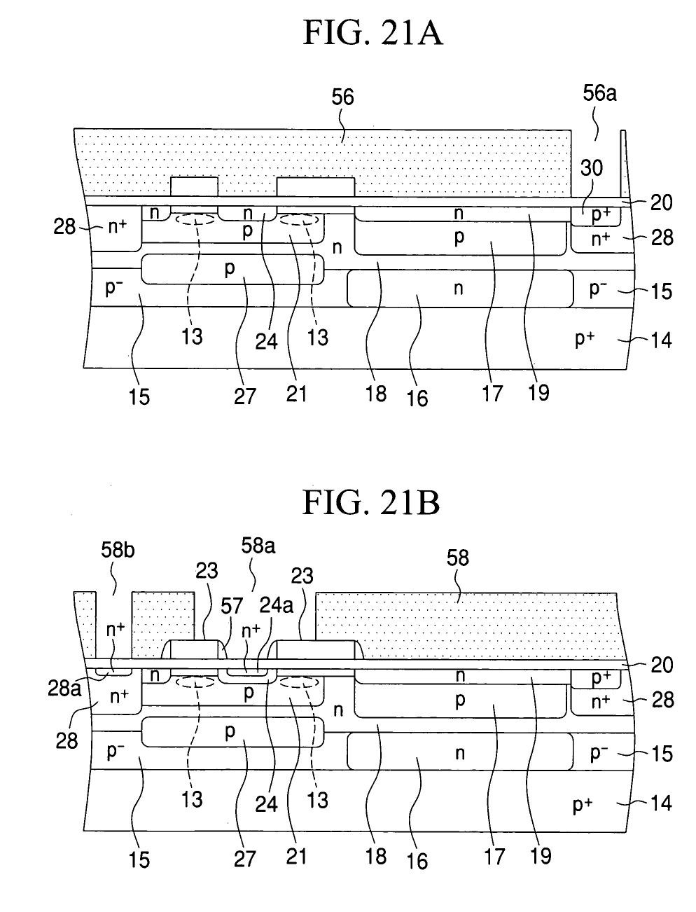

As shown in FIG. 21A, a resist mask 56 with an opening 56a is formed above the n⁺-type impurity region 28 located near the photo-diode 11. Then, the p-type impurity ions (B⁺) are implanted in a shallow region of the n⁺-type impurity region 28 through the opening 56a, so that the p⁺-type impurity region 30 as the lateral overflow drain is formed in the surface of the n⁺-type impurity region 28 near the photo-diode 11. The p⁺-type impurity region 30 and the charge generating region 17 are separated by the n-type layer 18.

After removing the resist mask 56, an insulation film is formed by chemical vapor deposition (CVD) process or the like, and then, side walls are formed on the lateral sides of the gate electrode 23 by anisotropic etching process. As shown in FIG. 21B, a resist mask 58 with openings 58a, 58b is formed. The opening 58a exposes the source region 24 and the gate electrode 23 partially. The opening 58b exposes the n⁺-type impurity region 28 as the drain region. By shallowly implanting the n-type impurities ion (Ph⁺) with high density, the n⁺-type contact layer 24a is formed in the surface of the source region 24, and the n⁺-type contact layer 28a is formed in the n⁺-type impurity region 28.

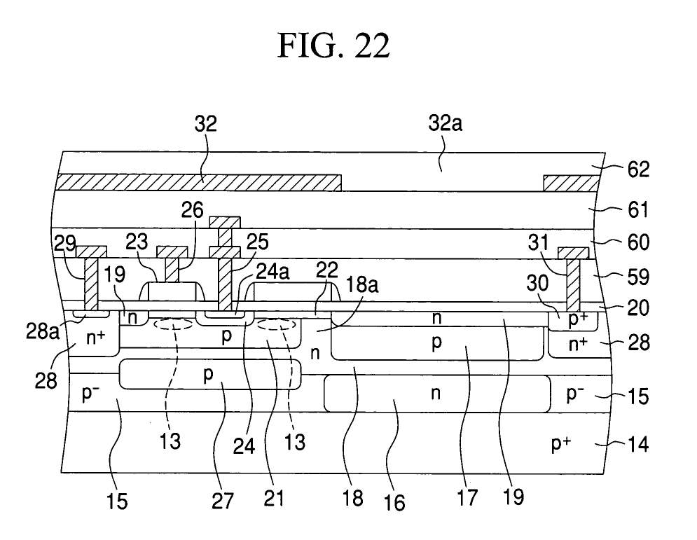

In FIG. 22, the insulation layers 59-62 are sequentially deposited after removing the resist mask 58. The plugs 25, 26, 29, 31 are formed to connect the contact layer 24a, 28a, gate electrodes 13 and the p⁺-type impurity region 30 to the corresponding line layers. On the insulation layer 61, the light-shielding film 32 with the light receiving window 32a to expose the photo-diode 11 is formed. In this way, the pixel 10 is fabricated.

The above embodiments do not limit the scope of the present invention. Various changes and modifications are possible in the present invention and may be understood to be within the scope of the present invention. In addition, the fabrication process of the pixel 10 described above is an example, and it is possible to change the order of the fabrication process.

Although all pixels 10 have the common n⁺-type impurity region 28 as the drain region in the above embodiments, it is possible to separate the n⁺-type impurity regions 28 for adjacent horizontal lines by providing the p⁺-type impurity region therebetween. In that case, during the elimination step S3, S10, the drain region driven in high-impedance state as well as the gate electrode 23 is boosted by the application voltage from the source region 24.

Instead of forming the self-aligned hole pocket 13, it is possible to form the hole pocket 13 by implanting the p-type impurity ions with high density through a resist mask with an opening to expose the area corresponding to the hole pocket 13.

In the above embodiments, the contact layers 24a, 28a are formed to electrically connect the plugs 25, 29 to the drain region and the source region 24. The contact layers 24a, 28a are not necessary if the plugs 25, 29 are respectively conductive to the drain region and the source region 24.

Although the MOS type solid-state imaging device according to the above embodiments has the p-type substrate 14, an n-type substrate is also possible. In that case, the photo-generated charges transferred from the photo-diode 11 to the photo-detector 12 are electrons, so the conductive type of each region is opposite to the above embodiments (p-type region in the above embodiments changes to n-type region, and vice versa), in order to achieve a similar characteristics.

1. A solid-state imaging device equipped with plural unit pixels each of which includes a photo-diode and a photo-detector on a substrate, the photo-diode comprising a charge generating region to generate charges upon light irradiation, the photo-detector comprising a charge accumulation region to accumulate the charges transferred from the charge generating region and generating a signal potential that changes in accordance with the amount of the charges in the charge accumulation region, the solid-state imaging device comprising:
a charge transfer region provided between the charge generating region and the charge accumulation region of the pixel, the charge transfer region forming a first potential barrier to the charges in the charge generating region, the first potential barrier being removable according to the applied voltage to the photo-detector.

2. The solid-state imaging device according to claim 1, further comprising a first charge eliminating region formed between the substrate and the charge accumulating region, the charges in the charge accumulating region being eliminated to the substrate via said first charge eliminating region when a certain voltage is applied to the photo-detector.

3. The solid-state imaging device according to claim 1, further comprising:
a second charge eliminating region formed near the charge generating region; and
a region, provided between the charge generating region and the second charge eliminating region, that forms a second potential barrier to the charges in the charge accumulating region, the second potential barrier being lower than the first potential barrier such that the charges in the charge eliminating region is overflowed to a surface side, opposite to the substrate, via the second charge eliminating region.

4. The solid-state imaging device according to claim 3, wherein the second potential barrier being removable according to the applied voltage to the second charge eliminating region.

5. The solid-state imaging device according to claim 1, wherein the charge generating region has one conductive type, same as the substrate, and the photo-diode comprises a first region with opposite conductive type that contacts the charge generating region, and
wherein the photo-detector is a field effect transistor and comprises:
a channel region formed on the surfaces of the charge accumulating region with one conductive type and the charge transfer region with opposite conductive type;
a gate electrode formed on a gate insulation layer that is formed on the channel region;
a source region having opposite conductive type, the source region near the charge accumulating region being connected to the channel region; and
a drain region with opposite conductive type that is apart from the source region by the channel region, the signal potential being generated in the source region.

6. The solid-state imaging device according to claim 5, wherein the plural pixels are arranged in first and second directions to form a matrix, the source regions of the pixels along the first direction being connected to one another, the gate electrodes of the pixel along the second direction being connected to one another, and the drain regions of all pixels being common.

7. The solid-state imaging device according to claim 6, further comprising:
a switch circuit capable of electrically connecting and disconnecting the source region and the drain region of the pixel; and
a first charge eliminating region formed between the substrate and the charge accumulating region, the charges in the charge accumulating region being eliminated to the substrate via the first charge eliminating region when the potentials of the charge accumulating region and the charge transfer region are increased by boosting up the voltage to the gate electrode,
wherein the voltage to the gate electrode is boosted by applying a voltage to the source and drain regions simultaneously while keeping the gate electrode at a high impedance state.

8. The solid-state imaging device according to claim 6, further comprising:
a second charge eliminating region formed near the charge generating region, the second charge eliminating region having one conductive type; and
a second region with opposite conductive type, provided between the charge generating region and the second charge eliminating region, the second region forming a second potential barrier to the charges in the charge accumulating region, the second potential barrier being lower than the first potential barrier such that the charges in the charge eliminating region is overflowed to a surface side, opposite to the substrate, via the second charge eliminating region.

9. The solid-state imaging device according to claim 8, wherein the second potential barrier being removable according to the applied voltage to the second charge eliminating region.

10. A method of driving the solid-state imaging device according to claim 2, comprising the steps of:
(a) removing the first potential barrier in the charge transfer region to transfer the charged from the charge generating region to the charge accumulating region;
(b) eliminating the charges in the charge accumulating region to the substrate through the first charge eliminating region;
(c) storing the photo-generated charges in the charge generating region for a predetermined period;
(d) removing the first potential barrier to transfer the charges from the charge generating region to the charge accumulating region;
(e) detecting the signal potential of the photo-detector as the first signal potential;
(f) eliminating the charges in the charge accumulating region to the substrate through the first charge eliminating region;
(g) detecting the signal potential of the photo-detector as the second signal potential; and
(h) subtracting the second signal potential from the first signal potential to output an image signal.

11. The method according to claim 10, wherein the steps (a) to (d) are carried out for all pixels at the same time, and the steps (e) to (h) are carried out for the pixels on a selected line.

12. The method according to claim 10, wherein the steps (c) and (d) are repeated in this order.

13. A method of driving the solid-state imaging device according to claim 2, the solid-state imaging device comprising:
a second charge eliminating region formed near the charge generating region; and
a region, provided between the charge generating region and the second charge eliminating region, that forms a second potential barrier to the charges in the charge accumulating region, the second potential barrier being removable according to the applied voltage to the second charge eliminating region,
the method comprising the steps of:
(a) removing the first potential barrier to transfer the charges from the charge generating region to the charge accumulating region;
(b) detecting the signal potential of the photo-detector as the first signal potential;
(c) eliminating the charges in the charge accumulating region to the substrate through the first charge eliminating region;
(d) detecting the signal potential of the photo-detector as the second signal potential;
(e) subtracting the second signal potential from the first signal potential to output an image signal; and
(f) removing the second potential barrier of all pixels to eliminating the charges in the charge generating region to the second charge eliminating region while carrying out the steps (b) to (e).
